(19) United States
(12) Patent Application Publication
(10) Pub. No.: US 2025/0390022 A1
(43) Pub. Date: Dec. 25, 2025

(54) EXTREME ULTRAVIOLET LIGHT GENERATION APPARATUS AND ELECTRONIC DEVICE MANUFACTURING METHOD

(71) Applicant: Gigaphoton Inc., Tochigi (JP)

(72) Inventors: Yoshiyuki HONDA, Oyama-shi (JP); Hirokazu HOSODA, Oyama-shi (JP); Tomoyoshi TOIDA, Oyama-shi (JP)

(73) Assignee: Gigaphoton Inc., Tochigi (JP)

(21) Appl. No.: 19/196,138

(22) Filed: May 1, 2025

(30) Foreign Application Priority Data
Jun. 21, 2024 (JP) 2024-100878

(51) Int. Cl. G03F 7/00; G03F 1/84

(52) U.S. Cl. CPC G03F 7/70041; G03F 1/84; G03F 7/70025; G03F 7/70033; G03F 7/7005

(57) ABSTRACT

An extreme ultraviolet light generation apparatus includes a chamber, a target supply unit configured to supply a target into the chamber, a first laser device configured to generate a diffusion target that is convex toward a travel direction of first prepulse laser light having a wavelength of 1 μm by irradiating the target with the first prepulse laser light, a second laser device configured to generate a low-density diffusion target by irradiating the diffusion target with second prepulse laser light having a wavelength of 1 μm, and a third laser device configured to generate extreme ultraviolet light by irradiating the low-density diffusion target with main pulse laser light having a wavelength of 1 μm.

### CROSS-REFERENCE TO RELATED APPLICATIONS

The present application claims the benefit of Japanese Patent Application No. 2024-100878, filed on Jun. 21, 2024, the entire contents of which are hereby incorporated by reference.

### BACKGROUND

### 1. Technical Field

The present disclosure relates to an extreme ultraviolet light generation apparatus and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2021/0026254

Patent Document 2: Japanese Patent Application Publication No. 2009-105006

Patent Document 3: US Patent Application Publication No. 2014/0264087

Patent Document 4: US Patent Application Publication No. 2012/0243566

Patent Document 5: U.S. Pat. No. 8,791,440

### SUMMARY

An extreme ultraviolet light generation apparatus according to an aspect of the present disclosure includes a chamber, a target supply unit configured to supply a target into the chamber, a first laser device configured to generate a diffusion target that is convex toward a travel direction of first prepulse laser light having a wavelength of 1 μm by irradiating the target with the first prepulse laser light, a second laser device configured to generate a low-density diffusion target by irradiating the diffusion target with second prepulse laser light having a wavelength of 1 μm, and a third laser device configured to generate extreme ultraviolet light by irradiating the low-density diffusion target with main pulse laser light having a wavelength of 1 μm.

An electronic device manufacturing method according to an aspect of the present disclosure includes generating extreme ultraviolet light using an extreme ultraviolet light generation apparatus, outputting the extreme ultraviolet light to an exposure apparatus, and exposing a photosensitive substrate to the extreme ultraviolet light in the exposure apparatus to manufacture an electronic device. Here, the extreme ultraviolet light generation apparatus includes a chamber, a target supply unit configured to supply a target into the chamber, a first laser device configured to generate a diffusion target that is convex toward a travel direction of first prepulse laser light having a wavelength of 1 μm by irradiating the target with the first prepulse laser light, a second laser device configured to generate a low-density diffusion target by irradiating the diffusion target with second prepulse laser light having a wavelength of 1 μm, and a third laser device configured to generate the extreme ultraviolet light by irradiating the low-density diffusion target with main pulse laser light having a wavelength of 1 μm.

An electronic device manufacturing method according to an aspect of the present disclosure includes inspecting a defect of a mask by irradiating the mask with extreme ultraviolet light generated by an extreme ultraviolet light generation apparatus, selecting a mask using a result of the inspection, and exposing and transferring a pattern formed on the selected mask onto a photosensitive substrate. Here, the extreme ultraviolet light generation apparatus includes a chamber, a target supply unit configured to supply a target into the chamber, a first laser device configured to generate a diffusion target that is convex toward a travel direction of first prepulse laser light having a wavelength of 1 μm by irradiating the target with the first prepulse laser light, a second laser device configured to generate a low-density diffusion target by irradiating the diffusion target with second prepulse laser light having a wavelength of 1 μm, and a third laser device configured to the generate extreme ultraviolet light by irradiating the low-density diffusion target with main pulse laser light having a wavelength of 1 μm.

### BRIEF DESCRIPTION OF THE DRAWINGS

Embodiments of the present disclosure will be described below merely as examples with reference to the accompanying drawings.

FIG. 1 shows the configuration of an LPP EUV light generation system according to a comparative example.

FIG. 2 shows a state in which a target is irradiated with first prepulse laser light in the comparative example.

FIG. 3 shows a state in which a diffusion target is irradiated with main pulse laser light in the comparative example.

FIG. 4 shows a center portion, which easily turns into plasma, and a peripheral portion, which does not easily turn into plasma, of the diffusion target in the comparative example.

FIG. 5 shows the configuration of the EUV light generation system according to a first embodiment.

FIG. 6 shows pulse waveforms of the first prepulse laser light, second prepulse laser light, and main pulse laser light which are concentrated on a plasma generation region in the first embodiment.

FIG. 7 shows a state in which the target is irradiated with the first prepulse laser light in the first embodiment.

FIG. 8 shows a state in which a diffusion target is irradiated with the second prepulse laser light in the first embodiment.

FIG. 9 shows a state in which a low-density diffusion target is irradiated with the main pulse laser light in the first embodiment.

FIG. 10 shows the configuration of a device for measuring the diffusion target.

FIG. 11 is an image of the diffusion target imaged by an imaging unit in the comparative example.

FIG. 12 is an image obtained by binarization of FIG. 11.

FIG. 13 is a graph showing the number of pixels of dark spots at each position in the Y direction in FIG. 12.

FIG. 14 is an image of the diffusion target imaged by the imaging unit in the first embodiment.

FIG. 15 is an image obtained by binarization of FIG. 14.

FIG. 16 is a graph showing the number of pixels of dark spots at each position in the Y direction in FIG. 15.

FIG. 17 is an image obtained by simulating the shape of a diffusion target under the irradiation conditions of the first embodiment.

FIG. 18 is an image obtained by simulating the shape of a low-density diffusion target under the irradiation conditions of the first embodiment.

FIG. 19 shows a result of binarizing the image shown in FIG. 18 in the same manner as in FIGS. 12 and 15 and fitting a Gaussian function as an approximate curve of the number of pixels of dark spots in the same manner as in FIGS. 13 and 16.

FIG. 20 is a graph showing a relationship between a delay time from when the target is irradiated with the first prepulse laser light to when the diffusion target is irradiated with the second prepulse laser light, and conversion efficiency.

FIG. 21 is a graph showing a relationship between a delay time from when the target is irradiated with the first prepulse laser light to when the diffusion target is irradiated with the second prepulse laser light, and ion energy of tin ions generated from the plasma generation region.

FIG. 22 shows the configuration of the EUV light generation system according to a second embodiment.

FIG. 23 schematically shows the configuration of an exposure apparatus connected to the EUV light generation system.

FIG. 24 schematically shows the configuration of an inspection apparatus connected to the EUV light generation system.

### DESCRIPTION OF EMBODIMENTS

### Contents

1. Comparative Example
   1.1 Configuration
   1.2 Operation
   1.3 Problem of comparative example
2. EUV light generation apparatus 1 which generates low density diffusion target 27c having Gaussian distribution shape
   2.1 Configuration
   2.2 Operation
   2.3 Irradiation conditions
   2.4 Shapes of diffusion targets 27a, 27b
   2.5 Shape of low-density diffusion target 27c
   2.6 Delay time Delay2
   2.7 Effect
3. EUV light generation apparatus 1 including polarization adjuster 349
   3.1 Configuration
   3.2 Operation
   3.3 Effect
4. Others
   4.1 Examples of EUV light utilization apparatus 6
   4.2 Processor 5
   4.3 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative example

### 1.1 Configuration

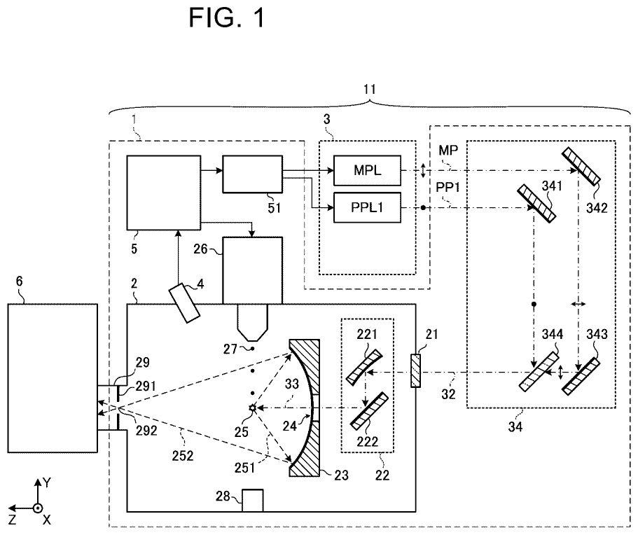

FIG. 1 shows the configuration of an LPP EUV light generation system 11 according to a comparative example. The comparative example of the present disclosure is an example recognized by the applicant as known only by the applicant, and is not a publicly known example admitted by the applicant. An EUV light generation apparatus 1 is used together with a laser device 3. In the present disclosure, a system including the EUV light generation apparatus 1 and the laser device 3 is referred to as the EUV light generation system 11.

The laser device 3 includes a first laser device PPL1 and a third laser device MPL. To facilitate comparison with the embodiments described later, in the comparative example, large ordinal numbers common to the embodiments may be used by skipping ordinal numbers of the first, second, and the like. The first laser device PPL1 outputs first prepulse laser light PP1 having a wavelength of 1 μm, and the third laser device MPL outputs main pulse laser light MP having a wavelength of 1 μm. The laser device for outputting laser light having a wavelength of 1 μm may be an neodymium-doped yttrium aluminum garnet (Nd:YAG) laser having a wavelength of 1.06 μm, a ytterbium-doped yttrium aluminum garnet (Yb:YAG) laser having a wavelength of 1.03 μm, and a Nd:YLF (neodymium-doped yttrium lithium fluoride) laser having a wavelength of 1.047 μm to 1.053 μm.

The EUV light generation apparatus 1 includes a chamber 2 and a target supply unit 26. The chamber 2 is a sealable container. The target supply unit 26 supplies a target 27 containing tin as a target substance into the chamber 2.

A through hole is formed in a wall of the chamber 2. The through hole is blocked by a window 21 and pulse laser light 32 output from the laser device 3 is transmitted through the window 21. An EUV light concentrating mirror 23 having a spheroidal reflection surface is arranged in the chamber 2. A multilayer reflective film in which molybdenum and silicon are alternately laminated is formed on the reflection surface. The EUV light concentrating mirror 23 has first and second focal points. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and pulse laser light 33 passes through the through hole 24.

The EUV light generation apparatus 1 includes a processor 5, a delay circuit 51, a target sensor 4, and the like. The configuration of the processor 5 will be described later. The delay circuit 51 is configured to output first and third delay trigger signals obtained by delaying a trigger signal output from the processor 5. The first delay trigger signal is input to the first laser device PPL1, and the third delay trigger signal is input to the third laser device MPL after the first delay trigger signal. The target sensor 4 detects at least one of the presence, trajectory, position, and velocity of the target 27. The target sensor 4 may have an imaging function.

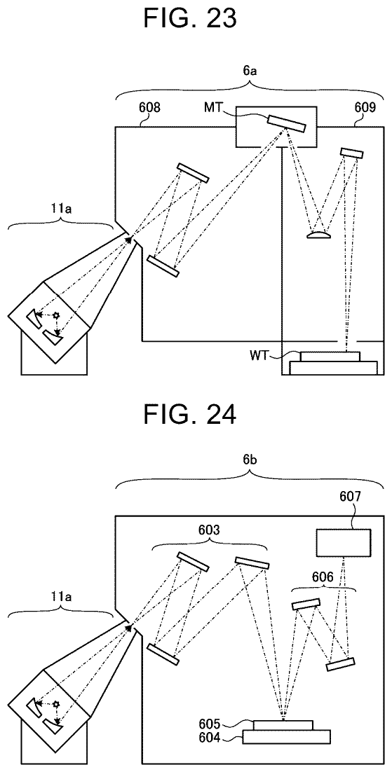

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 23 or an inspection apparatus 6b shown in FIG. 24. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating optical system 22, a target collection unit 28 for collecting the target 27, and the like. The laser light transmission device 34 includes optical elements such as high reflection mirrors 341 to 343 and a second beam combiner 344, and actuators (not shown) for adjusting the position, posture, and the like of the optical elements. The second beam combiner 344 is configured of a polarizing beam splitter. The laser light concentrating optical system 22 includes an off-axis paraboloidal concave mirror 221 and a high reflection mirror 222.

### 1.2 Operation

Operation of the EUV light generation system 11 will be described with reference to FIG. 1. The laser device 3 outputs the first prepulse laser light PP1 and the main pulse laser light MP in this order in accordance with the first and third delay trigger signals output from the delay circuit 51. The first prepulse laser light PP1 is linearly polarized light having a polarization direction perpendicular to the paper surface, and the main pulse laser light MP is linearly polarized light having a polarization direction parallel to the paper surface. The laser light transmission device 34 causes the first prepulse laser light PP1 and the main pulse laser light MP to be incident respectively on opposite surfaces of the second beam combiner 344 by the high reflection mirrors 341 to 343. The second beam combiner 344 reflects one of the first prepulse laser light PP1 and the main pulse laser light MP with high reflectance and transmits the other with high transmittance, so that the optical path axes of the both substantially coincide with each other and are output from the laser light transmission device 34. The prepulse laser light PP1 and the main pulse laser light MP output from the laser light transmission device 34 are collectively referred to as the pulse laser light 32. The pulse laser light 32 is transmitted through the window 21 and enters the chamber 2. The pulse laser light 32 passes through the laser light concentrating optical system 22 and is concentrated on the plasma generation region 25 as the pulse laser light 33.

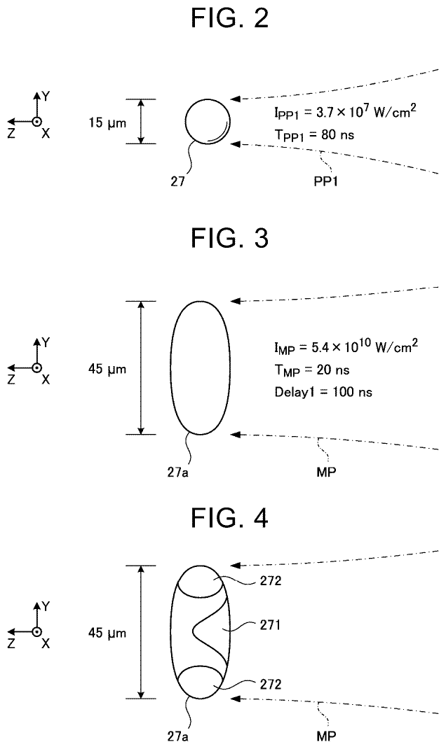

The target supply unit 26 outputs the droplet-shaped target 27 toward the plasma generation region 25 in the chamber 2. FIG. 2 shows a state in which the target 27 is irradiated with the prepulse laser light PP1 in the comparative example. The diameter of the target 27 is, for example, 15 μm. The target 27 irradiated with the first prepulse laser light PP1 is diffused, and becomes a diffusion target 27a shown in FIG. 3. FIG. 3 shows a state in which the diffusion target 27a is irradiated with the main pulse laser light MP in the comparative example. Compared with the droplet-shaped target 27, the energy of the main pulse laser light MP can be efficiently applied to the diffusion target 27a.

At least a portion of the diffusion target 27a irradiated with the main pulse laser light MP is gasified, a portion of the gasified target substance is turned into plasma, and radiation light 251 is radiated from the plasma (see FIG. 1). The EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. In the following description, the output direction of the EUV light is defined as the +Z direction, and the output direction of the target 27 is defined as the −Y direction. The +Z direction and the −Y direction are perpendicular to each other, and the directions perpendicular to both the +Z direction and the −Y direction are defined as the +X direction and the −X direction.

The processor 5 controls the entire EUV light generation system 11. The processor 5 processes a detection result of the target sensor 4. Based on the detection result of the target sensor 4, the processor 5 controls the output direction of the target 27, the timing of the trigger signal output to the delay circuit 51, and the like. Further, the processor 5 controls a delay time set in the delay circuit 51, the travel direction of the pulse laser light 32, the concentration position of the pulse laser light 33, and the like. The above-described various kinds of control are merely examples, and other control may be added as necessary.

### 1.3 Problem of Comparative Example

Irradiation conditions of the first prepulse laser light PP1 and the main pulse laser light MP in the comparative example are as follows.
Light intensity I_{PP1} of the first prepulse laser light PP1 at an irradiation position of the target 27: 3.7×10⁷ W/cm²
A pulse width T_{PP1} of the first prepulse laser light PP1: 80 ns
Light intensity I_{MP} of the main pulse laser light MP at an irradiation position of the diffusion target 27a: 5.4×10¹⁰ W/cm²
A pulse width T_{MP} of the main pulse laser light MP: 20 ns
A delay time Delay1 from when the target 27 is irradiated with the first prepulse laser light PP1 to when the diffusion target 27a is irradiated with the main pulse laser light MP: 100 ns

The pulse widths T_{PP1}, T_{MP} are represented as full width at half maximum. The light intensities I_{PP1}, I_{MP} correspond to I given by the following expression, where E is the pulse energy, T is the pulse width, and D is the focus diameter, that is, the total width of a part having an intensity equal to or more than 1/e² of the peak intensity at the irradiation position of the target 27 or the diffusion target 27a.

$$I = ( E / ( {π ( D / 2 )}^{2} ) ) / T$$

The delay time Delay1 is a time difference between peak times in the pulse time waveforms of the first prepulse laser light PP1 and the main pulse laser light MP. The delay time Delay1 is set in accordance with a required time from when the target 27 is irradiated with the first prepulse laser light PP1 to when the diffusion target 27a becomes a spheroid having a diameter equal to or less than the focus diameter (e.g., 45 μm) of the main pulse laser light MP.

FIG. 4 shows a center portion 271, which easily turns into plasma, and a peripheral portion 272, which does not easily turn into plasma, of the diffusion target 27a in the comparative example. Since the main pulse laser light MP has an intensity peak at the center of the optical path, a large energy is applied to the center portion 271 among the diffusion target 27a. However, even though many target substances are distributed in the peripheral portion 272 of the diffusion target 27a away from the center portion 271, the peripheral portion 272 is not applied with as much energy as the center portion 271. Therefore, even if the energy of the entire main pulse laser light MP is increased, the peripheral portion 272 may not be sufficiently turned into plasma.

With the irradiation conditions in the comparative example, a value CEcom of conversion efficiency CE from the energy of the laser light to the energy of the EUV light is 1.32%. Further improvement of the conversion efficiency CE is required.

### 2. EUV Light Generation Apparatus 1 Which Generates Low-density Diffusion Target 27c Having Gaussian Distribution Shape

### 2.1 Configuration

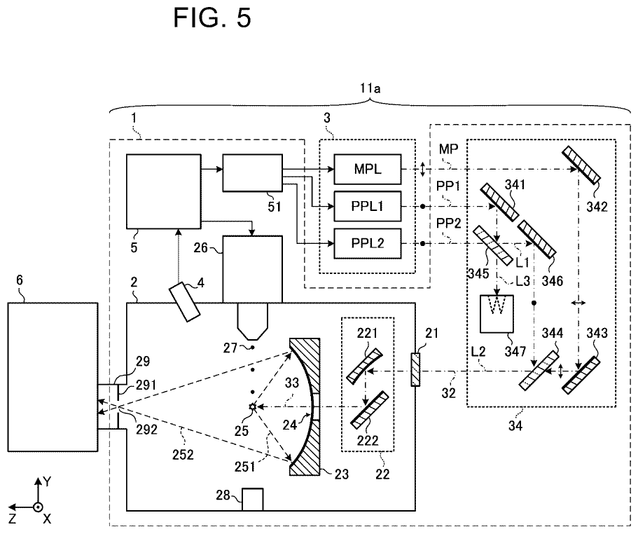

FIG. 5 shows the configuration of an EUV light generation system 11a according to a first embodiment. In the first embodiment, the laser device 3 includes a second laser device PPL2, and the laser light transmission device 34 includes a first beam combiner 345, a high reflection mirror 346, and a beam damper 347.

The second laser device PPL2 has the similar configuration to the first laser device PPL1. The first beam combiner 345 is configured by a partial reflection mirror and has a reflectance of, for example, 10% or more and 90% or less. The first beam combiner 345 is arranged at a position, where the optical path of the first prepulse laser light PP1 output from the first laser device PPL1 and the optical path of second prepulse laser light PP2 output from the second laser device PPL2 overlap, obliquely with respect to these optical paths.

### 2.2 Operation

The delay circuit 51 outputs a second delay trigger signal between the first and third delay trigger signals. The second laser device PPL2 outputs second prepulse laser light PP2 having a wavelength of 1 μm in accordance with the second delay trigger signal. The second prepulse laser light PP2 is linearly polarized light having the same polarization direction as the first prepulse laser light PP1.

The first prepulse laser light PP1 is incident on a first surface of the first beam combiner 345 via the high reflection mirror 341, and the second prepulse laser light PP2 is incident on a second surface of the first beam combiner 345 on the opposite side to the first surface. The first beam combiner 345 reflects a first portion of the first prepulse laser light PP1 and transmits a second portion of the second prepulse laser light PP2 to guide the first portion and the second portion to a first optical path L1. The first portion and the second portion propagating on the first optical path L1 are reflected by the high reflection mirror 346 and are incident on the second beam combiner 344. The first portion, the second portion, and the main pulse laser light MP are guided by the second beam combiner 344 to a second optical path L2 and output from the laser light transmission device 34. The first beam combiner 345 transmits a third portion of the first prepulse laser light PP1 different from the first portion and reflects a fourth portion of the second prepulse laser light PP2 different from the second portion, thereby guiding the third portion and the fourth portion to a third optical path L3. The beam damper 347 is located on the third optical path L3 and absorbs the energy of the third portion and the fourth portion. The first beam combiner 345 may guide the first portion and the second portion to the first optical path L1 as transmitting the first portion and reflecting the second portion, and guide the third portion and the fourth portion to the third optical path L3 as reflecting the third portion and transmitting the fourth portion.

Thus, the first portion of the first prepulse laser light PP1, the second portion of the second prepulse laser light PP2, and the main pulse laser light MP, which are caused to be substantially coaxial on the second optical path L2 enters the chamber 2 in this order, and are concentrated on the plasma generation region 25. In the following, description as the first prepulse laser light PP1 may be used even in a case of referring only to the first portion, and description as the second prepulse laser light PP2 may be used even in a case of referring only to the second portion.

### 2.3 Irradiation Conditions

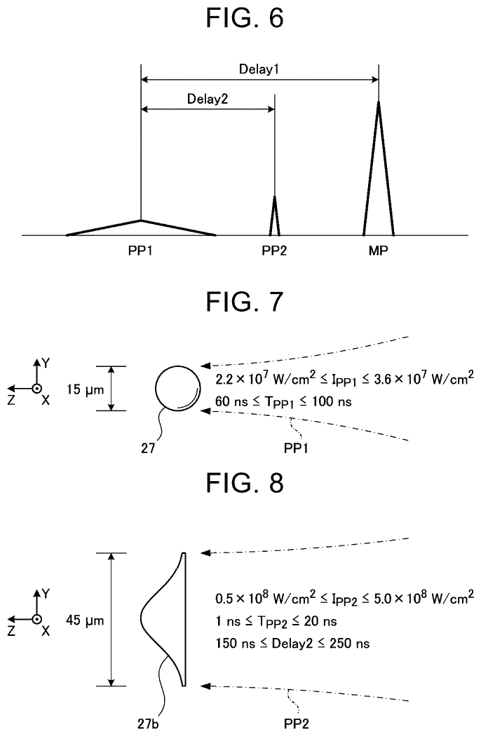

FIG. 6 shows pulse waveforms of the first prepulse laser light PP1, the second prepulse laser light PP2, and the main pulse laser light MP which are concentrated on the plasma generation region 25 in the first embodiment. A delay time Delay2 is a time difference between the peak times in the pulse time waveforms of the first prepulse laser light PP1 and the second prepulse laser light PP2.

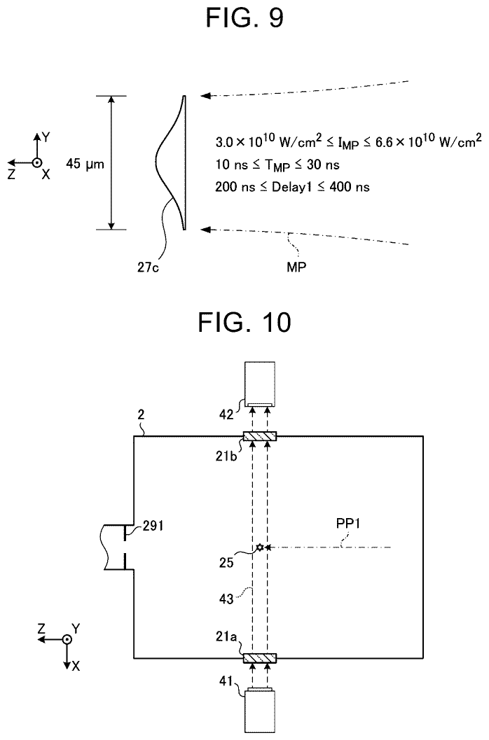

FIG. 7 shows a state in which the target 27 is irradiated with the first prepulse laser light PP1 in the first embodiment. FIG. 8 shows a state in which a diffusion target 27b is irradiated with the second prepulse laser light PP2 in the first embodiment. FIG. 9 shows a state in which a low-density diffusion target 27c is irradiated with the main pulse laser light MP in the first embodiment.

The light intensity I_{PP1} of the first prepulse laser light PP1 is 2.2×10⁷ W/cm² or higher and 3.6×10⁷ W/cm² or lower, and is lower than the light intensity I_{PP1} in the comparative example. As a result, as shown in FIG. 8, the diffusion target 27b convex toward the travel direction of the first prepulse laser light PP1 is generated. A preferred value of the light intensity I_{PP1} is 2.3×10⁷ W/cm². The pulse width T_{PP1} of the first prepulse laser light PP1 is 60 ns or more and 100 ns or less. A preferred value of the pulse width T_{PP1} is 80 ns as in the comparative example.

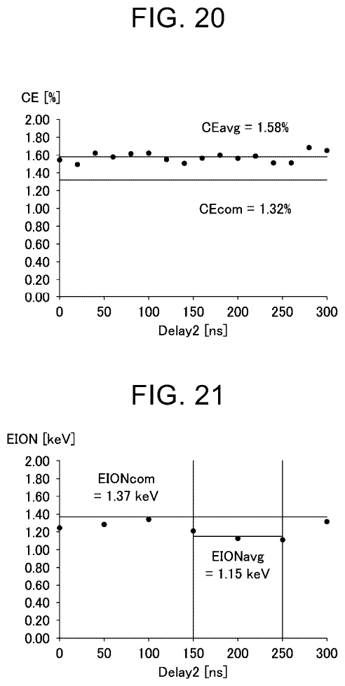

The delay time Delay2 from when the target 27 is irradiated with the first prepulse laser light PP1 to when the diffusion target 27b is irradiated with the second prepulse laser light PP2 is preferably 150 ns or more and 250 ns or less. The delay time Delay2 will be described later referring to FIGS. 20 and 21.

The light intensity I_{PP2} of the second prepulse laser light PP2 is 0.5×10⁸ W/cm² or higher and 5.0×10⁸ W/cm² or lower. As a result, as shown in FIG. 9, the low-density diffusion target 27c convex toward the travel direction of the second prepulse laser light PP2 is generated. A preferred value of the light intensity I_{PP2} is 1.1×10⁸ W/cm². The pulse width T_{PP2} of the second prepulse laser light PP2 is 1 ns or more and 20 ns or less. The pulse width T_{PP2} is preferably 1/100 or more and ⅕ or less of the pulse width T_{PP1}. A preferred value of the pulse width T_{PP2} is 7 ns.

The delay time Delay1 from when the target 27 is irradiated with the first prepulse laser light PP1 to when the low-density diffusion target 27c is irradiated with the main pulse laser light MP is preferably 200 ns or more and 400 ns or less. Here, when the delay time Delay2 is 200 ns or more, the delay time Delay1 is set longer than the delay time Delay2. A preferred value of the delay time Delay1 is 300 ns.

The light intensity I_{MP} of the main pulse laser light MP is 3.0×10¹⁰ W/cm² or higher and 6.6×10¹⁰ W/cm² or lower. A preferred value of the light intensity IMP is 5. 4×10¹⁰ W/cm² as in the comparative example. The pulse width T_{MP} of the main pulse laser light MP is 10 ns or more and 30 ns or less. A preferred value of the pulse width T_{MP} is 20 ns as in the comparative example.

The main pulse laser light MP has a light intensity distribution of a Gaussian distribution shape. The focus diameter of the main pulse laser light MP is preferably equal to or less than the size of the low-density diffusion target 27c in a direction perpendicular to the Z direction, and is 30 μm or more and 100 μm or less depending on the size of the low-density diffusion target 27c.

### 2.4 Shapes of Diffusion Targets 27a, 27b

FIG. 10 shows the configuration of a device for measuring the diffusion targets 27a, 27b. FIG. 10 corresponds to a view in which the inside of the chamber 2 is viewed in the −Y direction, which is the output direction of the target 27. In the chamber 2, two windows 21a, 21b are arranged with the plasma generation region 25 at which the diffusion targets 27a, 27b are generated interposed therebetween. A white flashlight 41 and an imaging unit 42 are arranged outside the chamber 2 with the windows 21a, 21b interposed therebetween. Illustration of other components inside the chamber 2 is omitted.

At a timing at which the delay time Delay1 elapses after the target 27 is irradiated with the first prepulse laser light PP1, the white flashlight 41 generates a light beam 43 that perpendicularly intersects with the optical path axis of the first prepulse laser light PP1 in the plasma generation region 25. At this time, both the second prepulse laser light PP2 and the main pulse laser light MP are not radiated. A part of the light beam 43 passes through the diffusion target 27a or 27b and the periphery thereof and enters the imaging unit 42, and the imaging unit 42 images the shape of the diffusion target 27a or 27b. A pulse laser or a light emitting diode may be used in place of the white flashlight 41.

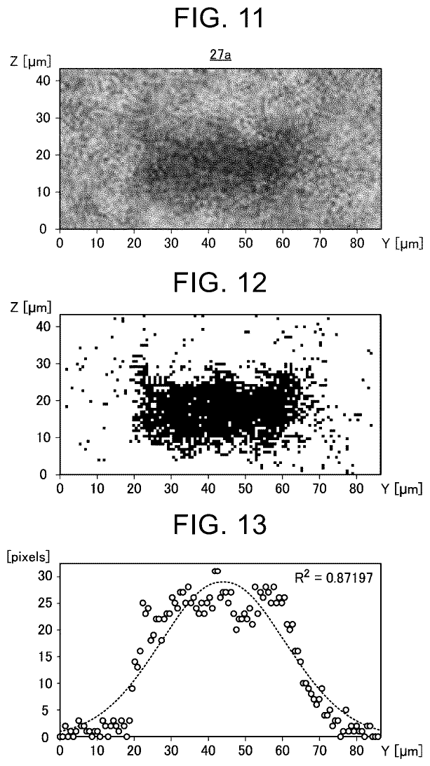

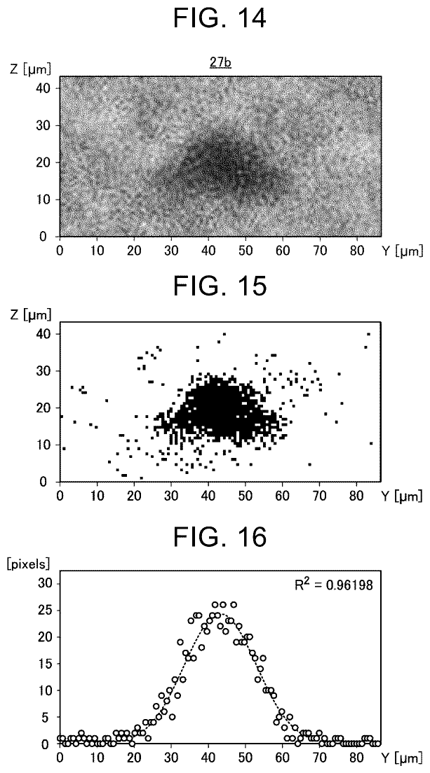

FIG. 11 shows an image of the diffusion target 27a imaged by the imaging unit 42 in the comparative example, and FIG. 14 shows an image of the diffusion target 27b imaged by the imaging unit 42 in the first embodiment. Each of the images in FIGS. 11 and 14 corresponds to an image of a space of 86 μm in the Y direction and 43 μm in the Z direction in the vicinity of the plasma generation region 25. The +Z direction is the travel direction of the first prepulse laser light PP1. The mist-like target substance contained in the diffusion target 27a or 27b scatters or absorbs a part of the light beam 43 generated by the white flashlight 41, and thus becomes a dark part in each image.

FIGS. 12 and 15 show images obtained by binarization of FIGS. 11 and 14, respectively. FIGS. 13 and 16 are graphs showing the number of pixels of dark spots at each position in the Y direction in FIGS. 12 and 15, respectively, where the horizontal axis represents the position in the Y direction and the vertical axis represents the number of pixels of dark spots.

In the first embodiment, the number of dark spots is peaked in the vicinity of the position of Y=43 μm, and the number of dark spots decreases from the position of the peak toward the +Y direction and the −Y direction. When a Gaussian function indicated by a broken line was fitted as an approximate curve for the number of pixels of dark spots in FIG. 16, the determination coefficient R² of the number of pixels of dark spots with respect to the Gaussian function was 0.96198, and the distribution of the number of pixels of dark spots and the Gaussian distribution were similar to each other.

On the other hand, in the comparative example, the number of pixels of dark spots is distributed substantially uniformly in the space from the vicinity of the position of Y=20 μm to the vicinity of the position of Y=60 μm. When the Gaussian function indicated by a broken line was fitted as an approximate curve for the number of pixels of dark spots in FIG. 13, the determination coefficient R² of the number of pixels of dark spots with respect to the Gaussian function was 0.87197, and the distribution of the number of pixels of dark spots and the Gaussian distribution did not coincide with each other.

### 2.5 Shape of Low-density Diffusion Target 27c

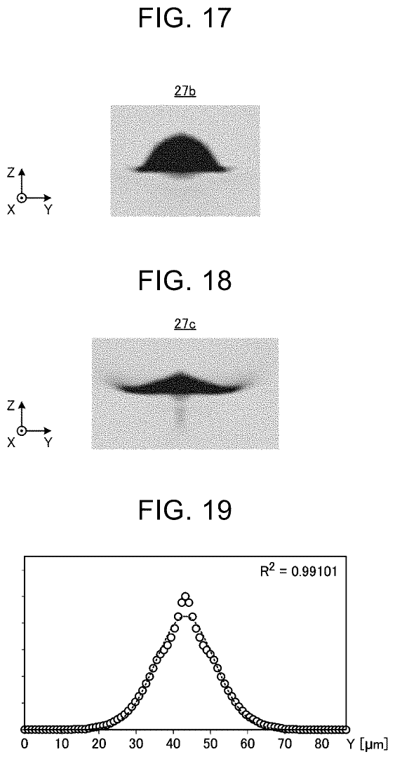

FIG. 17 is an image obtained by simulating the shape of the diffusion target 27b under the irradiation conditions of the first embodiment, and FIG. 18 is an image obtained by simulating the shape of the low-density diffusion target 27c under the irradiation conditions of the first embodiment. Since there is a slight plasma emission when the diffusion target 27b is irradiated with the second prepulse laser light PP2 and measurement is difficult with the device shown in FIG. 10, the shape of the low-density diffusion target 27c is obtained by simulation.

The diffusion target 27b shown in FIG. 17 has a shape including a gently sloped portion near both ends in the Y direction and a raised portion near the center in the Y direction, and matches well with the shape of the diffusion target 27b shown in FIG. 14 or 15. Accordingly, it can be said that the reliability of simulation is high.

The low-density diffusion target 27c shown in FIG. 18 has a flat shape shorter in the Z direction than the diffusion target 27b, but is similar to a Gaussian shape in including a portion having a gentle slope near both ends in the Y direction and a portion having a raised portion near the center in the Y direction.

FIG. 19 shows a result of binarizing the image shown in FIG. 18 in the same manner as in FIGS. 12 and 15 and fitting the Gaussian function as an approximate curve of the number of pixels of dark spots in the same manner as in FIGS. 13 and 16. In FIG. 19, the determination coefficient R² of the number of pixels of dark spots with respect to the Gaussian function was 0.99101, and the distribution of the number of pixels of dark spots was similar to the Gaussian distribution.

As described above, the intensity distribution of the main pulse laser light MP has a Gaussian distribution shape. The determination coefficient R² of the intensity distribution of the main pulse laser light MP with respect to the Gaussian function is preferably 0.99 or more.

In the first embodiment, the diffusion target 27b is irradiated with the second prepulse laser light PP2 to generate the low-density diffusion target 27c having a Gaussian distribution shape convex toward the travel direction of the second prepulse laser light PP2, and the low-density diffusion target 27c is irradiated with the main pulse laser light MP having an intensity distribution of a Gaussian distribution shape. Accordingly, since the center portion of the low-density diffusion target 27c at which many target substances exist is irradiated with the center portion of the main pulse laser light MP having a high intensity, it is considered that the energy of the main pulse laser light MP is efficiently applied to the low-density diffusion target 27c to turn into plasma. The determination coefficient R² of the distribution shape of the low-density diffusion target 27c with respect to the Gaussian function is preferably 0.95 or more.

It is desirable that the distribution of the target substance in the diffusion target 27b and the intensity distribution of the second prepulse laser light PP2 are matched, and that the distribution of the target substance in the low-density diffusion target 27c and the intensity distribution of the main pulse laser light MP are matched. Therefore, it is desirable that travel directions of the first prepulse laser light PP1, the second prepulse laser light PP2, and the main pulse laser light MP are the same direction as possible. It is desirable that the deviation in direction of any two of these optical path axes is preferably 1° or less.

### 2.6 Delay Time Delay2

FIG. 20 is a graph showing a relationship between the conversion efficiency CE and the delay time Delay2 from when the target 27 is irradiated with the first prepulse laser light PP1 to when the diffusion target 27b is irradiated with the second prepulse laser light PP2. In the first embodiment, even when the delay time Delay2 is changed from 0 ns to 300 ns, there was no significant difference in the conversion efficiency CE, and the average value CEavg of the conversion efficiency CE was 1.58%. According to the first embodiment, a higher conversion efficiency CE can be obtained as compared with the case in which the value CEcom of the conversion efficiency CE in the comparative example was 1.32%, but there is no significant difference in the value of the conversion efficiency CE due to the delay time Delay2. Accordingly, even when the diffusion target 27b is irradiated with the second prepulse laser light PP2, the shape change from the diffusion target 27b to the low-density diffusion target 27c is not significant, and it is estimated that the low-density diffusion target 27c has a Gaussian distribution shape.

FIG. 21 is a graph showing a relationship between an ion energy EION of tin ions generated from the plasma generation region 25 and the delay time Delay2 from when the target 27 is irradiated with the first prepulse laser light PP1 to when the diffusion target 27b is irradiated with the second prepulse laser light PP2. An ion energy EIONcom of tin ions in the comparative example was 1.37 keV. On the other hand, in the first embodiment, it was found that the ion energy EION of tin ions with the delay time Delay2 being in a range of 150 ns or more to 250 ns or less is low. An average value EIONavg of the ion energy EION of tin ions with the delay time Delay2 being in a range of 150 ns or more and 250 ns or less was 1.15 keV. When the ion energy EION of tin ions is low, the progress of degradation of the optical components such as the EUV light concentrating mirror 23 in the chamber 2 can be suppressed.

### 2.7 Effect

(1) According to the first embodiment, the EUV light generation apparatus 1 includes the chamber 2, the target supply unit 26, the first laser device PPL1, the second laser device PPL2, and the third laser device MPL. The target supply unit 26 supplies the target 27 into the chamber 2. The first laser device PPL1 irradiates the target 27 with the first prepulse laser light PP1 having a wavelength of 1 μm to generate the diffusion target 27b that is convex toward the travel direction of the first prepulse laser light PP1. The second laser device PPL2 irradiates the diffusion target 27b with the second prepulse laser light PP2 having a wavelength of 1 μm to generate the low-density diffusion target 27c. The third laser device MPL irradiates the low-density diffusion target 27c with the main pulse laser light MP having a wavelength of 1 μm to generate the EUV light.

Accordingly, since the diffusion target 27b convex in the travel direction of the first prepulse laser light PP1 is generated by the irradiation with the first prepulse laser light PP1 and the low-density diffusion target 27c is generated by the irradiation with the second prepulse laser light PP2, it is possible to efficiently apply the energy of the main pulse laser light MP to the low-density diffusion target 27c. Therefore, the conversion efficiency CE can be improved. Further, since the focus diameter can be reduced by using the main pulse laser light MP having a wavelength of 1 μm, the size of the light emission region of the EUV light can be reduced, and the EUV light having high brightness can be generated.

(2) According to the first embodiment, the second laser device PPL2 irradiates the diffusion target 27b with the second prepulse laser light PP2 to generate the low-density diffusion target 27c having a Gaussian distribution shape convex toward the travel direction of the second prepulse laser light PP2. Further, the third laser device MPL irradiates the low-density diffusion target 27c with the main pulse laser light MP having the intensity distribution of a Gaussian distribution shape.

Accordingly, by causing the low-density diffusion target 27c to have a Gaussian distribution shape, the energy of the main pulse laser light MP having the intensity distribution of a Gaussian distribution shape can be efficiently applied to the low-density diffusion target 27c, and the conversion efficiency CE can be improved.

(3) According to the first embodiment, the determination coefficient R² for the Gaussian function of the distribution shape of the low-density diffusion target 27c is 0.95 or more.

Accordingly, since the distribution shape of the low-density diffusion target 27c is a shape close to the Gaussian distribution, the energy of the main pulse laser light MP can be efficiently applied to many portions of the low-density diffusion target 27c.

(4) According to the first embodiment, the light intensity I_{PP1} at the position at which the target 27 is irradiated with the first prepulse laser light PP1 is 2.2×10⁷ W/cm² or higher and 3.6×10⁷ W/cm² or lower.

Accordingly, by making the light intensity I_{PP1} of the first prepulse laser light PP1 lower than that in the comparative example, the diffusion target 27b having a Gaussian distribution shape can be generated, and turning into plasma can be efficiently performed with irradiation with the second prepulse laser light PP2 and the main pulse laser light MP, so that the conversion efficiency CE can be improved.

(5) According to the first embodiment, the light intensity I_{PP2} of the second prepulse laser light PP2 at the position where the diffusion target 27b is irradiated is 0.5×10⁸ W/cm² or higher and 5.0×10⁸ W/cm² or lower.

Accordingly, by generating the low-density diffusion target 27c by ablating the diffusion target 27b to improve the absorption efficiency of the main pulse laser light MP, high conversion efficiency CE can be obtained.

(6) According to the first embodiment, the light intensity I_{MP} of the main pulse laser light MP at the position where the low-density diffusion target 27c is irradiated is 3.0×10¹⁰ W/cm² or higher and 6.6×10¹⁰ W/cm² or lower.

Accordingly, the low-density diffusion target 27c can be efficiently turned into plasma, and high conversion efficiency CE can be obtained.

(7) According to the first embodiment, the delay time Delay2 from when the target 27 is irradiated with the first prepulse laser light PP1 to when the diffusion target 27b is irradiated with the second prepulse laser light PP2 is 150 ns or more and 250 ns or less.

Accordingly, the ion energy EION of tin ions emitted from the plasma can be reduced, and deterioration of the optical elements can be suppressed.

(8) According to the first embodiment, the delay time Delay1 from when the target 27 is irradiated with the first prepulse laser light PP1 to when the low-density diffusion target 27c is irradiated with the main pulse laser light MP is 200 ns or more and 400 ns or less.

In the delay time Delay1, the Gaussian distribution shape of the low-density diffusion target 27c can be maintained, and thus the low-density diffusion target 27c can be efficiently turned into plasma by the main pulse laser light MP.

(9) According to the first embodiment, the focus diameter of the main pulse laser light MP is 30 μm or more and 100 μm or less.

Accordingly, since the difference between the size of the low-density diffusion target 27c and the focus diameter of the main pulse laser light MP is small, the low-density diffusion target 27c can be efficiently turned into plasma by the main pulse laser light MP.

(10) According to the first embodiment, the pulse width T_{PP1} of the first prepulse laser light PP1 is 60 ns or more and 100 ns or less.

Accordingly, by ablating the target 27 over time by the first prepulse laser light PP1, the diffusion target 27b having a Gaussian distribution shape can be obtained and turning into plasma can be efficiently performed by irradiation with the second prepulse laser light PP2 and the main pulse laser light MP.

(11) According to the first embodiment, the pulse width T_{PP2} of the second prepulse laser light PP2 is 1 ns or more and 20 ns or less.

Accordingly, the low-density diffusion target 27c can be generated without significantly changing the shape of the diffusion target 27b.

(12) According to the first embodiment, the pulse width T_{PP2} of the second prepulse laser light PP2 is 1/100 or more and ⅕ or less of the pulse width T_{PP1} of the first prepulse laser light PP1.

Accordingly, it is possible to generate the low-density diffusion target 27c having a Gaussian distribution shape without significantly changing the shape of the diffusion target 27b having a Gaussian distribution shape generated by the irradiation with the first prepulse laser light PP1.

(13) According to the first embodiment, the pulse width T_{MP} of the main pulse laser light MP is 10 ns or more and 30 ns or less.

Accordingly, the low-density diffusion target 27c can be efficiently turned into plasma by the main pulse laser light MP.

(14) According to the first embodiment, a deviation in direction of optical path axes of any two of the first prepulse laser light PP1, the second prepulse laser light PP2, and the main pulse laser light MP is 1° or less.

Accordingly, the distribution of the target substance in the diffusion target 27b and the intensity distribution of the second prepulse laser light PP2 are substantially matched, and the distribution of the target substance in the low-density diffusion target 27c and the intensity distribution of the main pulse laser light MP are substantially matched, so that the target substance can be efficiently turned into plasma.

(15) According to the first embodiment, the EUV light generation apparatus 1 includes the first beam combiner 345 and the beam damper 347. The first beam combiner 345 guides the first portion of the first prepulse laser light PP1 and the second portion of the second prepulse laser light PP2to the first optical path L1. The second beam combiner 344 guides the first portion and the second portion propagating on the first optical path L1 and the main pulse laser light MP to the second optical path L2. The first beam combiner 345 guides the third portion different from the first portion of the first prepulse laser light PP1 and the fourth portion different from the second portion of the second prepulse laser light PP2 to the third optical path L3 different from the first optical path L1. The beam damper 347 is located on the third optical path L3.

When the wavelengths of the first prepulse laser light PP1, the second prepulse laser light PP2, and the main pulse laser light MP are close to one another, the optical path of one of the three optical beams can be combined with a small loss, provided that the one has a polarization direction different from the others. However, there is a possibility that a loss occurs when the remaining two optical paths are combined. Here, by allowing the loss when combining the optical paths of the first prepulse laser light PP1 and the second prepulse laser light PP2, the loss when combining with the main pulse laser light MP is reduced, so that the total loss can be suppressed.

In other respects, the first embodiment is similar to the comparative example.

### 3. EUV Light Generation Apparatus 1 Including Polarization Adjuster 349

### 3.1 Configuration

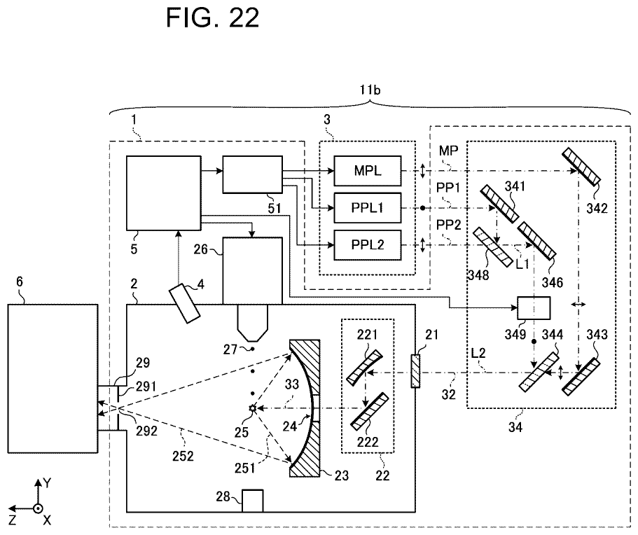

FIG. 22 shows the configuration of an EUV light generation system 11b according to a second embodiment. In the second embodiment, the laser light transmission device 34 includes a first beam combiner 348 instead of the first beam combiner 345 (see FIG. 5). The laser light transmission device 34 may not include the beam damper 347 and includes a polarization adjuster 349. The first beam combiner 348 is configured of a polarization beam splitter. The polarization adjuster 349 includes, for example, an electro-optical element and a power source device, and is arranged on the first optical path L1 between the first beam combiner 348 and the second beam combiner 344. The polarization adjuster 349 is configured to be switchable, in accordance with a control signal received from the processor 5, between a first state in which the polarization direction of the linearly polarized light passing through the electro-optical element is rotated by 90° and a second state in which the linearly polarized light is caused to pass without the polarization direction thereof rotated.

### 3.2 Operation

In the second embodiment, the polarization direction of the second prepulse laser light PP2 output from the second laser device PPL2 is parallel to the paper surface, unlike the polarization direction of the first prepulse laser light PP1 output from the first laser device PPL1. The first beam combiner 348 guides the first prepulse laser light PP1 and the second prepulse laser light PP2 to the first optical path L1 by reflecting one of first prepulse laser light PP1 and the second prepulse laser light PP2 with high reflectance and transmitting the other thereof with high transmittance.

The processor 5 switches the state of the polarization adjuster 349 between when the first prepulse laser light PP1 passes through the polarization adjuster 349 and when the second prepulse laser light PP2 passes through the polarization adjuster 349 so that the polarization directions of the first prepulse laser light PP1 and the second prepulse laser light PP2 each having passed through the polarization adjuster 349 become a third polarization direction. The third polarization direction may be the same as either the first polarization direction or the second polarization direction.

The second beam combiner 344 reflects one of the main pulse laser light MP, and the first prepulse laser light PP1 and the second prepulse laser light PP2, and transmits the other thereof, thereby guiding the main pulse laser light MP, and the first prepulse laser light PP1 and the second prepulse laser light PP2 to the second optical path L2 to be output from the laser light transmission device 34.

Thus, the first prepulse laser light PP1, the second prepulse laser light PP2, and the main pulse laser light MP, which are caused to be substantially coaxial on the second optical path L2 enter the chamber 2 in this order, and are concentrated on the plasma generation region 25.

### 3.3 Effect

(16) According to the second embodiment, the EUV light generation apparatus 1 includes the first beam combiner 348, the polarization adjuster 349, the processor 5, and the second beam combiner 344. The first beam combiner 348 guides the first prepulse laser light PP1 having the first polarization direction and the second prepulse laser light PP2 having the second polarization direction different from the first polarization direction to the first optical path L1. The polarization adjuster 349 is arranged on the first optical path L1. The processor 5 switches the state of the polarization adjuster 349 between when the first prepulse laser light PP1 passes through the polarization adjuster 349 and when the second prepulse laser light PP2 passes through the polarization adjuster 349 so that the polarization directions of the first prepulse laser light PP1 and the second prepulse laser light PP2 each having passed through the polarization adjuster 349 become the third polarization direction. The second beam combiner 344 guides the first prepulse laser light PP1 and the second prepulse laser light PP2 each having the third polarization direction, and the main pulse laser light MP having the fourth polarization direction different from the third polarization direction to the second optical path L2.

Accordingly, due to that the optical paths of the first prepulse laser light PP1 and the second prepulse laser light PP2 having different polarization directions are combined, and then the polarization direction thereof is caused to be different from the polarization direction of the main pulse laser light MP, it is possible to combine the optical paths of the three optical beams with a small loss.

In other respects, the second embodiment is similar to the first embodiment.

### 4. Others

### 4.1 Examples of EUV Light Utilization Apparatus 6

FIG. 23 schematically shows the configuration of the exposure apparatus 6a connected to the EUV light generation system 11a. The exposure apparatus 6a as the EUV light utilization apparatus 6 (see FIG. 5) includes a mask irradiation unit 608 and a workpiece irradiation unit 609. The mask irradiation unit 608 illuminates, via a reflection optical system, a mask pattern of a mask table MT with the EUV light incident from the EUV light generation system 11a. The workpiece irradiation unit 609 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 24 schematically shows the configuration of the inspection apparatus 6b connected to the EUV light generation system 11a. The inspection apparatus 6b as the EUV light utilization apparatus 6 (see FIG. 5) includes an illumination optical system 603 and a detection optical system 606. The illumination optical system 603 reflects the EUV light incident from the EUV light generation system 11a to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. A defect of the mask 605 is inspected based on the image of the mask 605 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 6a.

In FIGS. 23 and 24, the EUV light generation system 11b may be used instead of the EUV light generation system 11a.

### 4.2 Processor 5

The processor 5 may be physically configured as hardware to execute various processes included in the present disclosure. For example, the processor 5 may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor 5 may be programmed as software to execute the various processes included in the present disclosure. For example, the processor 5 may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 4.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. An extreme ultraviolet light generation apparatus comprising:
a chamber;
a target supply unit configured to supply a target into the chamber;
a first laser device configured to generate a diffusion target that is convex toward a travel direction of first prepulse laser light having a wavelength of 1 μm by irradiating the target with the first prepulse laser light;
a second laser device configured to generate a low-density diffusion target by irradiating the diffusion target with second prepulse laser light having a wavelength of 1 μm; and
a third laser device configured to generate extreme ultraviolet light by irradiating the low-density diffusion target with main pulse laser light having a wavelength of 1 μm.

2. The extreme ultraviolet light generation apparatus according to claim 1,
wherein the second laser device generates the low-density diffusion target having a Gaussian distribution shape convex toward a travel direction of the second prepulse laser light by irradiating the diffusion target with the second prepulse laser light, and
the third laser device irradiates the low-density diffusion target with the main pulse laser light having an intensity distribution of a Gaussian distribution shape.

3. The extreme ultraviolet light generation apparatus according to claim 2,
wherein a determination coefficient of a distribution shape of the low-density diffusion target with respect to a Gaussian function is 0.95 or more.

4. The extreme ultraviolet light generation apparatus according to claim 1,
wherein a light intensity of the first prepulse laser light at a position at which the target is irradiated with the first prepulse laser light is 2.2×10⁷ W/cm² or higher and 3.6×10⁷ W/cm² or lower.

5. The extreme ultraviolet light generation apparatus according to claim 1,
wherein a light intensity of the second prepulse laser light at a position at which the diffusion target is irradiated with the second prepulse laser light is 0.5×10⁸ W/cm² or higher and 5.0×10⁸ W/cm² or lower.

6. The extreme ultraviolet light generation apparatus according to claim 1,
wherein a light intensity of the main pulse laser light at a position at which the low-density diffusion target is irradiated with the main pulse laser light is 3.0×10¹⁰ W/cm² or higher and 6.6×10¹⁰ W/cm² or lower.

7. The extreme ultraviolet light generation apparatus according to claim 1,
wherein a delay time from when the target is irradiated with the first prepulse laser light to when the diffusion target is irradiated with the second prepulse laser light is 150 ns or more and 250 ns or less.

8. The extreme ultraviolet light generation apparatus according to claim 1,
wherein a delay time from when the target is irradiated with the first prepulse laser light to when the low-density diffusion target is irradiated with the main pulse laser light is 200 ns or more and 400 ns or less.

9. The extreme ultraviolet light generation apparatus according to claim 1,
wherein a focus diameter of the main pulse laser light is 30 μm or more and 100 μm or less.

10. The extreme ultraviolet light generation apparatus according to claim 1,
wherein a pulse width of the first prepulse laser light is 60 ns or more and 100 ns or less.

11. The extreme ultraviolet light generation apparatus according to claim 1,
wherein a pulse width of the second prepulse laser light is 1 ns or more and 20 ns or less.

12. The extreme ultraviolet light generation apparatus according to claim 1,
wherein a pulse width of the second prepulse laser light is 1/100 or more and ⅕ or less of a pulse width of the first prepulse laser light.

13. The extreme ultraviolet light generation apparatus according to claim 1,
wherein a pulse width of the main pulse laser light is 10 ns or more and 30 ns or less.

14. The extreme ultraviolet light generation apparatus according to claim 1,
wherein a deviation in direction of optical path axes of any two of the first prepulse laser light, the second prepulse laser light, and the main pulse laser light is 1° or less.

15. The extreme ultraviolet light generation apparatus according to claim 1, further comprising:
a first beam combiner configured to guide a first portion of the first prepulse laser light and a second portion of the second prepulse laser light to a first optical path;
a second beam combiner configured to guide the first portion and the second portion propagating on the first optical path and the main pulse laser light to a second optical path; and
a beam damper;
wherein the first beam combiner is configured to guide a third portion different from the first portion of the first prepulse laser light and a fourth portion different from the second portion of the second prepulse laser light to a third optical path different from the first optical path, and
the beam damper is located on the third optical path.

16. The extreme ultraviolet light generation apparatus according to claim 1, further comprising:
a first beam combiner configured to guide the first prepulse laser light having a first polarization direction and the second prepulse laser light having a second polarization direction different from the first polarization direction to a first optical path;
a polarization adjuster arranged on the first optical path;
a processor configured to switch a state of the polarization adjuster between when the first prepulse laser light passes through the polarization adjuster and when the second prepulse laser light passes through the polarization adjuster so that the polarization directions of the first prepulse laser light and the second prepulse laser light each having passed through the polarization adjuster become a third polarization direction; and
a second beam combiner configured to guide the first prepulse laser light and the second prepulse laser light both having the third polarization direction and the main pulse laser light having a fourth polarization direction different from the third polarization direction to a second optical path.

17. An electronic device manufacturing method, comprising:
generating extreme ultraviolet light using an extreme ultraviolet light generation apparatus;
outputting the extreme ultraviolet light to an exposure apparatus; and
exposing a photosensitive substrate to the extreme ultraviolet light in the exposure apparatus to manufacture an electronic device,
the extreme ultraviolet light generation apparatus including:
a chamber;
a target supply unit configured to supply a target into the chamber;
a first laser device configured to generate a diffusion target that is convex toward a travel direction of first prepulse laser light having a wavelength of 1 μm by irradiating the target with the first prepulse laser light;
a second laser device configured to generate a low-density diffusion target by irradiating the diffusion target with second prepulse laser light having a wavelength of 1 μm; and
a third laser device configured to generate the extreme ultraviolet light by irradiating the low-density diffusion target with main pulse laser light having a wavelength of 1 μm.

18. The electronic device manufacturing method according to claim 17,
wherein a delay time from when the target is irradiated with the first prepulse laser light to when the diffusion target is irradiated with the second prepulse laser light is 150 ns or more and 250 ns or less.

19. An electronic device manufacturing method, comprising:
inspecting a defect of a mask by irradiating the mask with extreme ultraviolet light generated by an extreme ultraviolet light generation apparatus;
selecting a mask using a result of the inspection; and
exposing and transferring a pattern formed on the selected mask onto a photosensitive substrate,
the extreme ultraviolet light generation apparatus including:
a chamber;
a target supply unit configured to supply a target into the chamber;
a first laser device configured to generate a diffusion target that is convex toward a travel direction of first prepulse laser light having a wavelength of 1 μm by irradiating the target with the first prepulse laser light;
a second laser device configured to generate a low-density diffusion target by irradiating the diffusion target with second prepulse laser light having a wavelength of 1 μm; and
a third laser device configured to the generate extreme ultraviolet light by irradiating the low-density diffusion target with main pulse laser light having a wavelength of 1 μm.

20. The electronic device manufacturing method according to claim 19,
wherein a delay time from when the target is irradiated with the first prepulse laser light to when the diffusion target is irradiated with the second prepulse laser light is 150 ns or more and 250 ns or less.
